(19) United States
(12) Patent Application Publication
(10) Pub. No.: US 2006/0094165 A1
(43) Pub. Date: May 4, 2006

(54) Method for fabricating semiconductor components

(76) Inventors: Harry Hedler, Germering (DE); Thorsten Meyer, Dresden (DE)

Correspondence Address: FISH & RICHARDSON PC, P.O. BOX 1022, MINNEAPOLIS, MN, 55440-1022, US

(21) Appl. No.: 11/257,775

(22) Filed: Oct. 24, 2005

(30) Foreign Application Priority Data
Oct. 29, 2004 (DE) 10 2004 052 921.3

(51) Int. Cl. H01L 21/20

(52) U.S. Cl. 438/141

(57) ABSTRACT

In a method for fabricating semiconductor components a first carrier is provided and at least one semiconductor component is arranged on the first carrier between ist boundary lines. The semiconductor has at least one semiconductor contact-connection region which is located on a first surface of the first carrier. Then conical trenches having sidewalls and a trench bottom are introduced into the first carrier, wherein the sidewalls are inclined by an angle between 0° to 90° with respect to the first carrier and the trenches are arranged along the boundary lines. A conductive layer is applied and patterned in order to form a rewiring device for connecting the semiconductor contact-connection region to one of the inclined sidewalls. A second carrier having an adhesive surface is fitted to the side of the first surface and the first carrier is thinned from one side, which is opposite to the first surface, at least until the trench bottom is exposed in order to singulate the semiconductor component being rewired.

### RELATED APPLICATION

Under 35 U.S.C. § 119, this application claims the benefit of a foreign priority application filed in Germany, serial number 10 2004 052 921.3, filed Oct. 29, 2004.

### FIELD OF THE INVENTION

The present invention relates to a method for fabricating semiconductor components having external contact-connection.

### DESCRIPTION OF THE RELATED ART

While semiconductor components are being processed at the wafer level, semiconductor contact-connection regions (pads) are applied to the semiconductor components (chips) in order to be connected to the semiconductor component. However, these semiconductor contact-connection regions have dimensions which are too small for these semiconductor contact-connection regions to be directly contact-connected using method techniques associated with final assembly of semiconductor components. Provision is therefore made of external contact-connections which have larger dimensions and are at a greater distance from one another, and these external contact-connections are connected to the semiconductor contact-connection regions using a rewiring device.

Although the present invention is described with reference to the fabrication of rewired semiconductor components having external contact-connections for final assembly, the invention is not restricted thereto but rather relates, in general, to methods for fabricating semiconductor components having contact-connections.

Typical methods for fabricating semiconductor components for final assembly are described with reference to FIGS. 14, 15 and 16. After the semiconductor components have been singulated by sawing the wafer, the semiconductor component 21 is embedded in a substrate 23. The connection region 22 of the semiconductor component 21 is contact-connected using bonding wires 24 which are connected to an interposer substrate 25. Solder balls 26 are finally applied to this interposer substrate. In this case, there are various methods which differ in terms of whether the semiconductor contact-connection region 22 is arranged such that it faces (FIG. 14). or faces away from (FIG. 15) the solder balls 26. Another method provides for directly applying solder balls 30 to the semiconductor substrate 21 and connecting said solder balls to the semiconductor contact-connection region 22. The semiconductor component 21 with the solder balls 30 is placed on an interposer substrate 27 which enables rewiring between the solder balls 30 which are close together and external solder balls 26 which are further apart. In this method, an underfilling is also introduced between the semiconductor substrate and the interposer 27 (FIG. 16).

A multiplicity of individual method steps for fabricating the external contact-connection are disadvantageously required for these semiconductor technology methods. In addition, some of these method steps cannot be carried out in parallel for a plurality of semiconductor components; these include, inter alia, the fitting of the solder balls and the contact-connection using the bonding wires. Serially processing each individual semiconductor component leads to a relatively high outlay in terms of time and costs for an individual semiconductor component.

### SUMMARY OF THE INVENTION

It is an object of the present invention to provide an improved method which manages with a smaller number of method steps. Another object is to reduce the number of method steps which are to be carried out serially.

The inventive method arranges for the provision of a carrier, on which one or more semiconductor components are arranged between boundary lines, a semiconductor contact-connection region of the semiconductor component being located on a first surface of the carrier. Conical trenches having inclined sidewalls are then introduced into the carrier, the trenches running along the boundary lines. The inclined sidewalls have an inclination in the range of 0° to 90° with respect to the carrier. A rewiring device which connects at least one of the semiconductor contact-connection regions to one of the inclined sidewalls of a trench is formed in a subsequent method step. The carrier is then thinned from one side which is opposite the first surface. In this case, the carrier is thinned at least until the trench bottom is exposed. After removal of the adhesive carrier which was applied immediately before the carrier was thinned, rewired singulated semiconductor components thus result.

The boundary lines indicate the edge of the semiconductor components. The conically tapering trenches are to be understood as meaning that the trenches have a larger diameter at the first surface than at the trench bottom.

One aspect of the present invention is to use the conical trenches to form contact regions and, at the same time, to singulate the semiconductor components.

In a restricted version of this inventive method, the conical trenches are introduced by sawing with a conical saw blade.

In another restricted version of this inventive method, the insulating layer in the semiconductor contact-connection region is at least partially removed before the rewiring device is formed.

The carrier may be a front end wafer.

In a further restricted version of the inventive method, before the carrier is provided, the following method steps are carried out: semiconductor components of a front end wafer are singulated, and the semiconductor components are embedded in a carrier substrate. This makes it possible to adapt the dimensions of the semiconductor components, for example after a change to the integration layer, to existing normalized dimensions of housings. In addition, the carrier substrate may be used to reduce thermal stresses, on account of different coefficients of thermal expansion, in accordance with generally known methods.

An insulating layer may be applied to a surface (which is opposite the first surface) of the carrier after the carrier has been thinned. This insulating layer is used to insulate the semiconductor component from a printed circuit board or another carrier. Another refinement of the present invention provides for arranging the singulated rewired semiconductor component on a printed circuit board, an electrical connection between at least one contact region of the printed circuit board and a section of the rewiring device being provided on one of the inclined sidewalls.

A second singulated rewired component may be arranged, an electrical connection between at least one contact region of the printed circuit board and a section of the rewiring device being provided on one of the inclined sidewalls of the second singulated rewired component. This method makes it possible to stack components, the stack advantageously not being very high since the semiconductor components were greatly thinned beforehand.

The singulated rewired components may be encapsulated with a potting compound. This makes it possible to protect against mechanical effects on the semiconductor component.

### DESCRIPTION OF THE DRAWINGS

FIG. 1 is a partial cross section through a front end wafer;

FIGS. 2 to 8 are partial sectional views for illustrating a first embodiment of the inventive method;

FIG. 9 is a partial sectional view for illustrating a second embodiment;

FIG. 10 is a plan view of the second embodiment;

FIG. 11 is a partial sectional view of a third embodiment of the present invention;

FIG. 12 is a partial sectional view of a fourth embodiment of the present invention;

FIG. 13 is a partial sectional view of a fifth embodiment of the present invention; and

FIGS. 14 to 16 show partial sectional views for explaining typical methods for fabricating rewired semiconductor components.

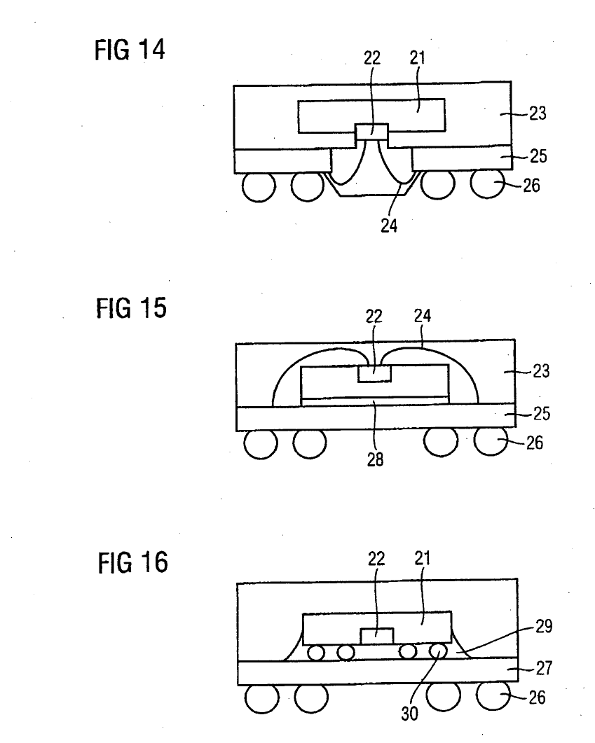

### DESCRIPTION OF THE PREFERRED EMBODIMENTS

In the Figures, unless specified otherwise, identical reference symbols denote identical or functionally identical components.

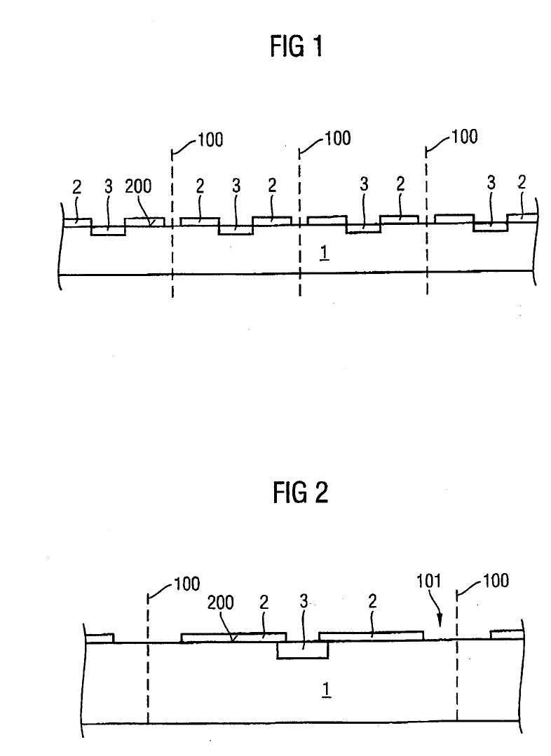

FIG. 1 illustrates a partial section through a front end wafer. One or more semiconductor components are arranged on a surface 200 of a semiconductor substrate 1. The semiconductor components have a semiconductor contact-connection region 3 which is arranged on the surface 200. Regions of the surface 200 which do not adjoin the semiconductor contact-connection region are covered by a polymer layer 200. Instead of the polymer layer 2, other layers may also be applied in order to protect the semiconductor components. The individual semiconductor components adjoin one another at the boundary line 100. No active semiconductor structures are situated in the immediate region around the boundary line 100.

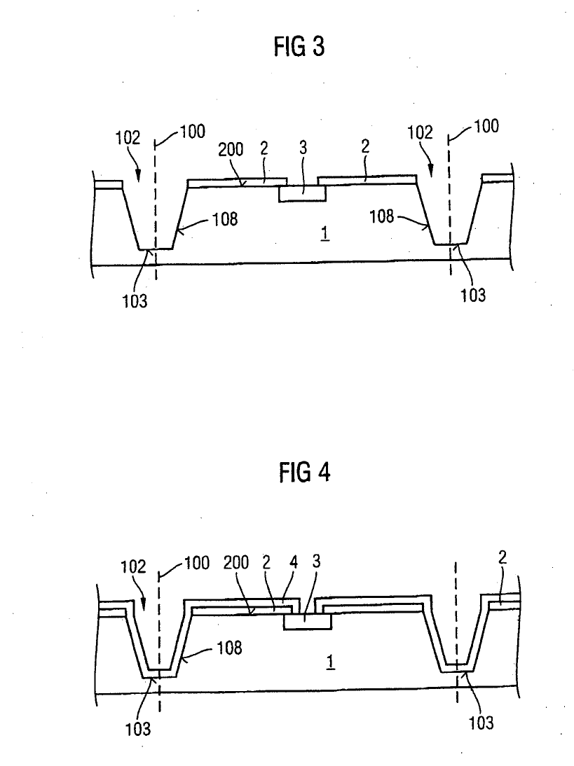

FIG. 2 illustrates a partial section for illustrating a first embodiment of the present invention. A detail from FIG. 1 having a single semiconductor component is illustrated in this case. A sawing track 101 is introduced along the boundary line 100. This sawing track 101 borders the semiconductor component. In a first method step, a conically shaped saw blade is used to saw a trench 102 into the substrate 1 along the sawing track 101 or the boundary lines 100. The conical saw blade results in a trench bottom 103 whose dimensions are smaller than the opening of the trench at the surface 200. In addition, the sidewalls 108 of the trench are inclined (FIG. 3). In a subsequent method step, a nonconductive insulation layer 4 is applied to the wafer (FIG. 4). The nonconductive insulation layer 4 covers both the trench 102 and the entire surface 200 and the semiconductor contact-connection region 3. A patterning process is used to remove the insulation layer 4 at least partially from the semiconductor contact-connection region 3 (FIG. 5). A rewiring device 5 is then applied using known method steps such as the application of a resist layer, lithography, sputtering etc. The rewiring device connects the semiconductor contact-connection region 3 to a region of a trench wall 108 of a trench 102 that adjoins the semiconductor component (FIG. 6). The inclined sidewalls 108 of the trench make it possible for a conductive, advantageously metallic, rewiring to be applied to said trench. The inclination is needed, on the one hand, to deposit a conductive material, advantageously a metal, on the inclined sidewalls 108. In a subsequent method step (FIG. 7), an adhesive carrier layer 6 is applied to the side of the surface 200 of the entire substrate 1. The underside of the substrate 1 is then removed, for example by polishing or grinding. The substrate 1 is thinned until the trench bottom 103 is exposed. In this manner, the substrate 1 no longer has any material in the regions 104. The semiconductor components which have thus been singulated are only held together by the adhesive carrier 6. In a further method step, a nonconductive insulation layer is applied to the rear side of the substrate 1. The insulation layer may be applied in the vapor phase and/or by spraying (FIG. 8). In a last method step, the adhesive carrier 6 is removed from the singulated semiconductor components.

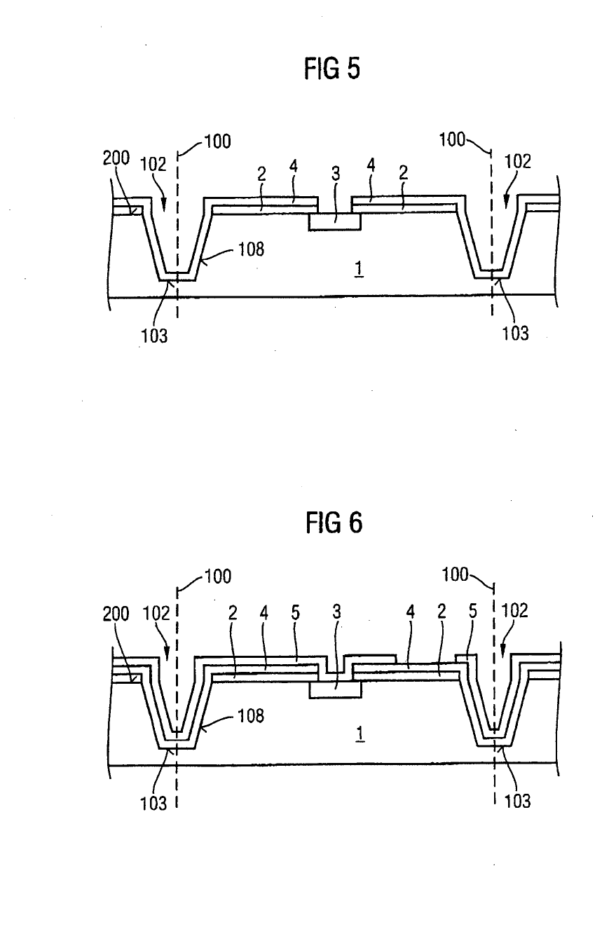

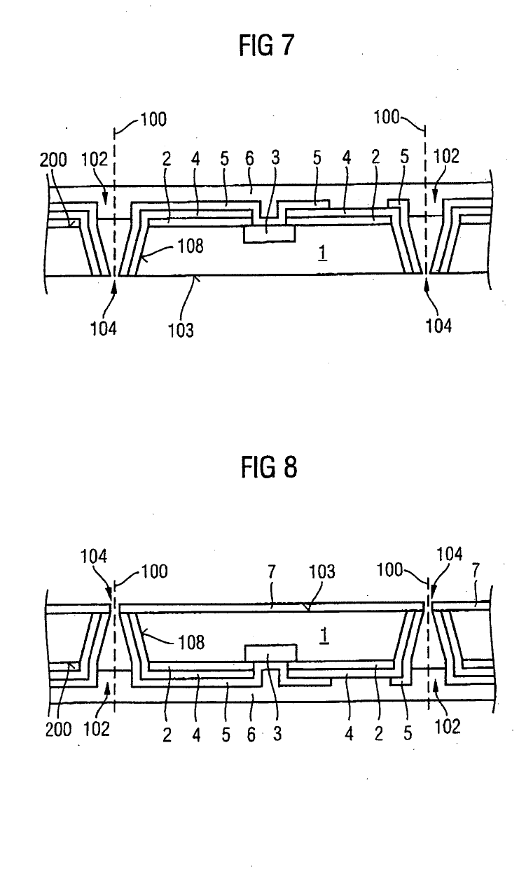

FIG. 9 illustrates a semiconductor component which was fabricated using the method of the first embodiment. In a further method step, this semiconductor component is arranged on a carrier 10, for example a printed circuit board, having contact-connection regions 11. A solder material 12 connects the rewiring 5 in the regions of the inclined sidewalls 108 to the contact-connection regions 11. FIG. 10 illustrates a plan view of the semiconductor component shown in FIG. 9. The individual semiconductor contact-connection regions 3 of the semiconductor component are connected, via the rewiring device 5, to the individual contact-connection regions 11 using the solder material 12. The geometric design of the rewiring device 5 is only exemplary, and any desired profiles of the rewiring device 5 on the semiconductor component are possible in this case using known patterning methods.

One fundamental advantage of the method of the first embodiment is that, except for the sawing and accommodation of the semiconductor components after singulation, all of the method steps are carried out in parallel for the entire wafer. In addition, there is no need to individually serially fit bonding wires and/or solder balls, for example, for each semiconductor component. This therefore results in a very cost-effective method since the costs of an individual method step are distributed among the plurality of components of a wafer. Another fundamental advantage is that there is no need for interposers for the rewiring, thus additionally saving costs since the fabrication of these interposers is very expensive. Another advantage of the method is that the semiconductor component which is fabricated has a very low height. This is a direct consequence of thinning and, at the same time, of the fact that it is possible to dispense with elevated solder balls, a potting compound and/or supporting intermediate layers.

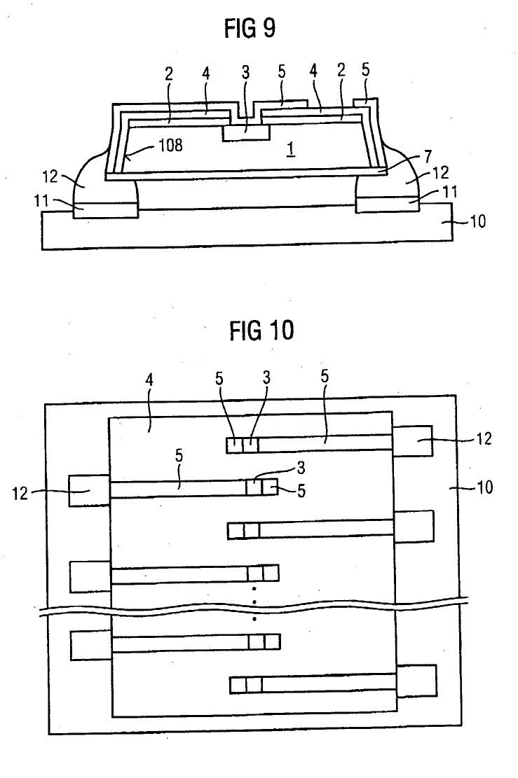

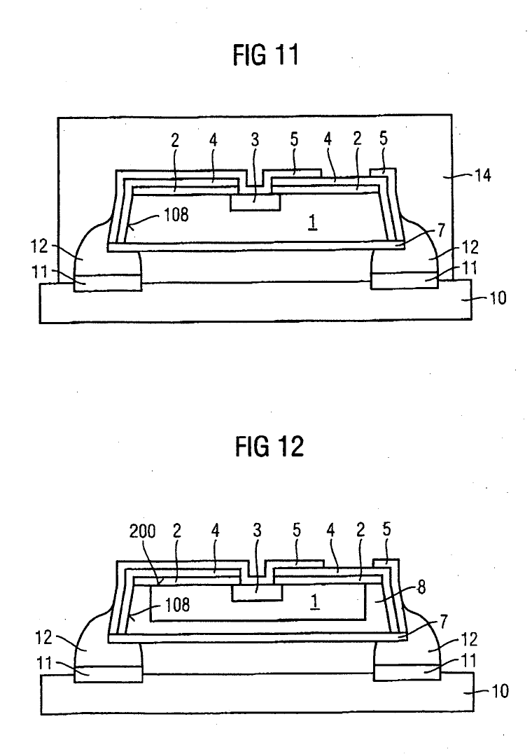

FIG. 11 illustrates another embodiment of the present invention, the semiconductor component being potted using a potting compound 14 after it has been mounted on a carrier 10 (reconstituted wafer). The potting compound 14 advantageously protects the component from mechanical loads. FIG. 12 illustrates a semiconductor component which was fabricated in accordance with a third embodiment of the present invention. To this end, the front end wafer was sawn in a first method step in order to singulate the semiconductor components. The singulated semiconductor components are arranged in the form of a grid on a surface of an auxiliary carrier, the semiconductor components being at a distance from one another and the semiconductor contact-connection region 3 being arranged such that it faces the auxiliary carrier. The semiconductor components are then covered by a potting compound 8 and the auxiliary carrier is removed. The matrix comprising the potting compound 8 and the semiconductor components arranged in the latter can now be processed, instead of a front end wafer, analogously to the method of the first exemplary embodiment. In this case, the boundary line 10 runs between two semiconductor components within the matrix of the potting compound 8. The materials for the potting compound 8 may be selected in such a manner that they compensate for thermomechanical stresses which are produced as a result of different coefficients of expansion of the printed circuit boards, the rewiring device and/or the semiconductor substrate. Another advantage of this matrix is that dimensions of a semiconductor component which are becoming smaller can be adapted to existing methods on the basis of new fabrication methods.

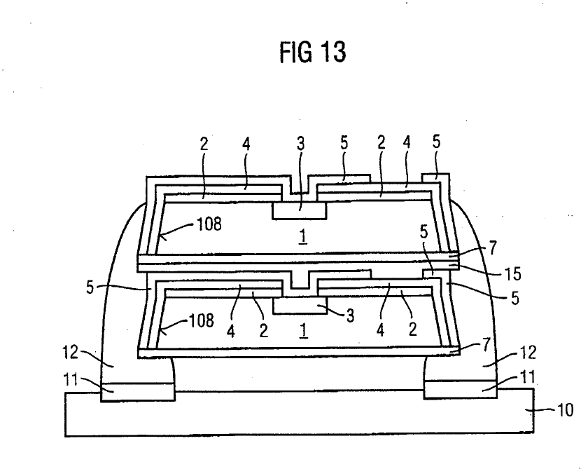

FIG. 13 illustrates another embodiment of the present invention, this method being used to stack a plurality of semiconductor components on top of one another. An adhesion layer 15 is applied to the rewiring device of a first semiconductor component which is arranged on a carrier 10, for example in accordance with the method described with respect to FIG. 9. Another semiconductor component is arranged on this adhesion layer 15. The inclined sidewalls 108 of the top and bottom semiconductor components are connected to the contact-connection regions 11 of the carrier 10 using a solder material 12. Since the height of the semiconductor components is only in the range of 50 to 150 micrometers, more than two semiconductor components can also be stacked on top of one another and connected to one another using the solder material 12.

The trenches 102 may likewise be introduced into the substrate 1 using a punch provided that the substrate is soft enough in the region of the boundary lines 100. Other methods provide for the trenches to be burned or drilled into the substrate using a laser light beam.

### DESCRIPTION OF THE PREFERRED EMBODIMENTS

Although modifications and changes may be suggested by those skilled in the art, it is the intention of the inventors to embody within the patent warranted heron all changes and modifications as reasonably and properly come within the scope of their contribution to the art.

We claim as our invention:

1. A method for fabricating semiconductor components, comprising the steps of:
providing a first carrier,
arranging at least one semiconductor component on said first carrier between boundary lines of said first carrier; said at least one semiconductor having at least one semiconductor contact-connection region which is located on a first surface of said first carrier;
introducing, into said first carrier, conical trenches having sidewalls and a trench bottom; said sidewalls being inclined by an angle in the range of 0° to 90° with respect to said first carrier and said trenches being arranged along said boundary lines;
applying and patterning a conductive layer in order to form a rewiring device for connecting said at least one said semiconductor contact-connection region to one of said inclined sidewalls of said trenches;
fitting a second carrier having an adhesive surface to the side of said first surface;
thinning said first carrier from one side, which is opposite to said first surface, at least until said trench bottom is exposed in order to singulate said at least one semiconductor component being rewired.

2. The method of claim 1, comprising sawing said conical trenches with a conical saw blade.

3. The method of claim 1, comprising, before the step of applying and patterning said conductive layer, the following steps:
applying a first insulating layer to said first surface and said conical trenches; and
removing said first insulating layer at least partially from said semiconductor contact-connection region.

4. The method of claim 1, wherein said first carrier is a front end wafer.

5. The method of claim 1, comprising, before providing said first carrier, the steps of:
singulating said at least one semiconductor component from a front end wafer; and
embedding said at least one semiconductor component in a carrier substrate.

6. The method of claim 1, comprising applying a second insulating layer to a surface being opposite to said first surface of said first carrier after said first carrier has been thinned.

7. The method of claim 1, comprising arranging said at least one semiconductor component being rewired on a printed circuit board after said second carrier has been removed; an electrical connection between at least one contact region of said printed circuit board and a section of said at least one rewiring device being provided on one of said inclined sidewalls.

8. The method of claim 7, comprising arranging two of said components being pre-wired onto each other; an electrical connection between at least one contact region of said printed circuit board and a section of said rewiring device being provided on one of said inclined sidewalls of one of said two components being rewired.

9. The method of claim 7, wherein said two components being rewired are encapsulated with a potting compound.

10. The method of claim 8, wherein said two components being rewired are encapsulated with a potting compound.

11. The method of claim 1, wherein said inclined sidewall has an angle of inclination in the range of 45° to 80° with respect to said first carrier.
